(19) United States
(12) Patent Application Publication
(10) Pub. No.: US 2017/0036620 A1
(43) Pub. Date: Feb. 9, 2017

(54) WIRE HARNESS

(71) Applicant: YAZAKI CORPORATION, Tokyo (JP)

(72) Inventor: Mitsuharu NAGAHASHI, Susono-shi (JP)

(73) Assignee: YAZAKI CORPORATION, Tokyo (JP)

(21) Appl. No.: 15/296,166

(22) Filed: Oct. 18, 2016

Related U.S. Application Data
(63) Continuation of application No. PCT/JP2015/064016, filed on May 15, 2015.

(30) Foreign Application Priority Data
May 21, 2014 (JP) 2014-104943

(51) Int. Cl. B60R 16/02; H01B 7/00; H05K 9/00; H02G 3/04

(52) U.S. Cl. CPC B60R 16/0215; H02G 3/0462; H01B 7/0045; H05K 9/00

(57) ABSTRACT

A wire harness includes: a high-voltage circuit including a plurality of unshielded electric wires; and a low-voltage circuit. The high-voltage circuit and the low-voltage circuit are disposed in parallel. The high-voltage circuit is stored in a resin tube together with the low-voltage circuit in a state in which the high-voltage circuit is covered with a shielding member.

### CROSS REFERENCE TO RELATED APPLICATION(S)

This application is a continuation of PCT application No. PCT/JP2015/064016, which was filed on May 15, 2015, based on Japanese Patent

Application (No. 2014-104943) filed on May 21, 2014, the contents of which are incorporated herein by reference.

### BACKGROUND OF THE INVENTION

1. Field of the Invention

The present invention relates to a wire harness, and particularly relates to a wire harness in which a high-voltage circuit and a low-voltage circuit are disposed in parallel. 2. Description of the Related Art

A wire harness according to JP-A-2010-47033 has been known as a wire harness for establishing electric connection between high-voltage devices mounted on a hybrid car or an electric car, and also establishing electric connection between low-voltage devices.

The wire harness according to JP-A-2010-47033 is a long wire harness to be arranged through a vehicle underfloor. The wire harness has a configuration including a high-voltage circuit, a low-voltage circuit, and first to third tubes. The high-voltage circuit includes six high-voltage shielded electric wires. The low-voltage circuit includes two low-voltage electric wires. In the wire harness configured thus, three of the six high-voltage shielded electric wires are stored in the first tube, and the other three high-voltage shielded electric wires are stored in the second tube. Further, the two low-voltage electric wires are stored in the third tube. The first to third tubes are disposed in parallel.

### SUMMARY OF THE INVENTION

In the aforementioned background-art wire harness, high-voltage shielded electric wires are used. Therefore, there is a problem as follows. That is, each high-voltage shielded electric wire has a configuration and a structure in which a braid is provided as a shielding member outside a core consisting of a conductor and an insulator, and a sheath is provided further on the braid. Thus, the high-voltage shielded electric wire is a comparatively thick electric wire. Thus, due to a plurality of such thick electric wires, there is a problem that a large space must be secured.

In addition, in the aforementioned background-art wire harness, the first to third tubes are used so that the circuits can be arranged separately from each other. Therefore, there are other problems as follows. That is, there is a problem that the number of components increases. In addition, there is a problem that a space large enough to dispose the first to third tubes in parallel must be secured.

The present invention has been developed in consideration of the aforementioned situation. An object of the invention is to provide a wire harness capable of attaining space saving and reduction in number of components.

In order to solve the foregoing problems, a wire harness according to the invention has the following configurations (1) to (7).

(1) A wire harness including a high-voltage circuit including a plurality of unshielded electric wires, and a low-voltage circuit, wherein the high-voltage circuit and the low-voltage circuit are disposed in parallel, and wherein the high-voltage circuit is stored in a resin tube together with the low-voltage circuit in a state in which the high-voltage circuit is covered with a shielding member.

(2) The wire harness according to the aforementioned configuration (1), wherein each of the unshielded electric wires is an electric wire having a sheathless structure including a conductor and an insulator.

(3) The wire harness according to the aforementioned configuration (1) or (2), wherein the shielding member is one of a braid, a tape made of metal foil, and a sheet made of metal foil.

(4) The wire harness according to any one of the aforementioned configurations (1) to (3), wherein the low-voltage circuit includes one or a plurality of unshielded electric wires which have a sheathless structure including a conductor and an insulator.

(5) The wire harness according to any one of the aforementioned configurations (1) to (4), wherein the wire harness is arranged in a site including a vehicle underfloor.

(6) The wire harness according to the aforementioned configuration (5), wherein at least a part of the resin tube corresponding to the vehicle underfloor has a flat shape in which the high-voltage circuit and the low-voltage circuit is stored so as to be arrayed in parallel, and the resin tube includes a flexible tube portion having flexibility, and a straight tube portion serving as a part to be arranged straightly.

(7) The wire harness according to the aforementioned configuration (5), wherein at least a part of the resin tube corresponding to the vehicle underfloor has a flat shape in which the high-voltage circuit and the low-voltage circuit is stored so as to be arrayed in parallel, and the resin tube includes only a flexible tube portion having flexibility.

In the wire harness according to the invention having the aforementioned configuration (1), a high-voltage circuit and a low-voltage circuit are stored in a single resin tube at the same time and in parallel. Accordingly, there is an advantage that the number of components can be reduced in comparison with that in the background-art example. In addition, according to the invention, unshielded electric wires are used in the high-voltage circuit. Accordingly, the electric wires can be made into thinner electric wires than well-known shielded electric wires. As a result, there is an advantage that space saving can be attained.

According to the invention having the aforementioned configuration (2), a sheathless structure is used in the high-voltage circuit. Accordingly, there is an advantage that the high-voltage circuit can be made thinner at least correspondingly to the absence of any sheath. That is, there is an advantage that space saving can be attained.

According to the invention having the aforementioned configuration (3), it is a matter of course that a shielding function can be obtained by use of any one of a braid, a tape made of metal foil, and a sheet made of metal foil. In addition, when any one of the aforementioned three is used, even the high-voltage circuit covered with the shielding member can be prevented from being thickened. As a result, there is an advantage that space saving can be attained.

According to the invention having the aforementioned configuration (4), a sheathless structure is used in the low-voltage circuit. Accordingly, there is an advantage that the low-voltage circuit can be made thinner at least correspondingly to the absence of any sheath. That is, there is an advantage that space saving can be attained.

According to the invention having the aforementioned configuration (5), due to the space saving, there is an advantage that the wire harness can be arranged with reduced height even in a vehicle underfloor short in distance from the ground.

According to the invention having the aforementioned configuration (6), a resin tube having a flat shape is used. Accordingly, there is an advantage that the distance from the ground can be secured even when the wire harness is arranged in the vehicle underfloor. In addition, according to the invention, a resin tube including a flexible tube portion and a straight tube portion is used. Accordingly, there is another advantage that the flexible tube portion and the straight tube portion can be used suitably in accordance with a part to be bent and a part to be made straight.

According to the invention having the aforementioned configuration (7), a resin tube having a flat shape is used. Accordingly, there is an advantage that the distance from the ground can be secured even when the wire harness is arranged in the vehicle underfloor. In addition, according to the invention, a resin tube made into a flexible tube portion as a whole is used. Accordingly, there is another advantage that the resin tube can be bent at desired positions.

According to the invention, it is possible to provide a wire harness capable of attaining space saving and reduction in number of components.

The invention has been described briefly. Further, the details of the invention will be made clearer through the following mode for carrying out the invention (hereinafter referred to as “embodiment”) with reference to the accompanying drawings.

### BRIEF DESCRIPTION OF THE DRAWINGS

FIG. 1 is a schematic view showing a state in which a wire harness according to Embodiment 1 of the invention has been arranged.

FIG. 2 is a perspective view of the wire harness according to Embodiment 1.

FIG. 3 is a sectional view taken on line A-A in FIG. 2.

FIG. 4 is a sectional view of a wire harness according to a modification.

### DETAILED DESCRIPTION OF THE EXEMPLARY EMBODIMENTS

A wire harness is long enough to be arranged through a vehicle underfloor. The wire harness has a configuration in which a high-voltage circuit covered with a shielding member is stored in a resin tube together with a low-voltage circuit. The high-voltage circuit includes a plurality of high-voltage unshielded electric wires. Each electric wire has a sheathless structure made of a conductor and an insulator.

On the other hand, the low-voltage circuit includes an electric wire having a sheathless structure made of a conductor and an insulator. The shielding member is any one of a braid, a tape made of metal foil, and a sheet made of metal foil. Of the resin tube, at least a part corresponding to the vehicle underfloor is formed into a flat shape in which the high-voltage circuit and the low-voltage circuit can be stored so as to be arrayed in parallel.

### Embodiment 1

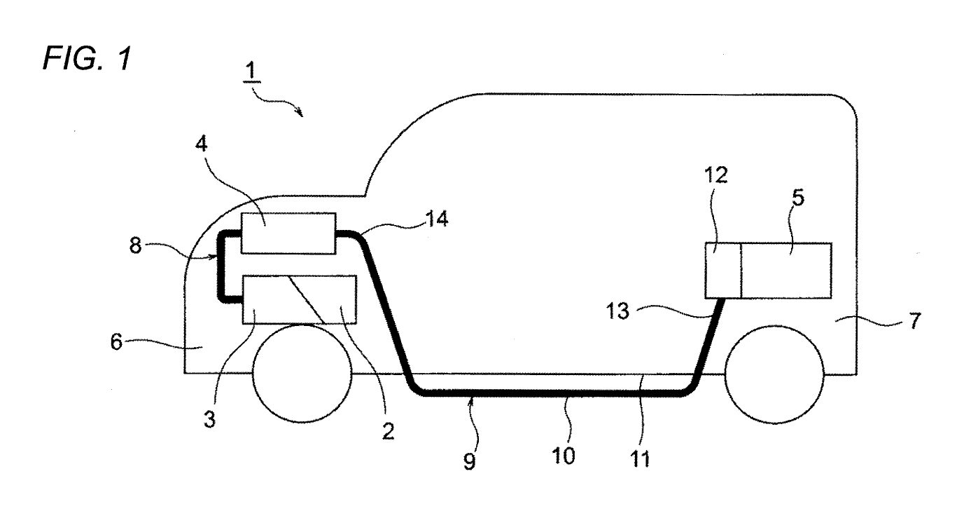

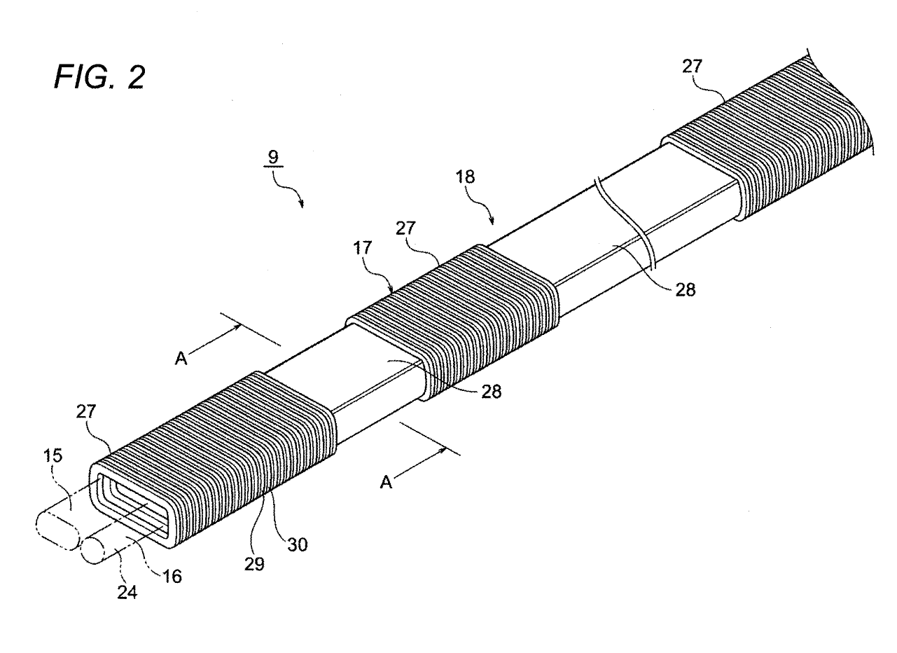

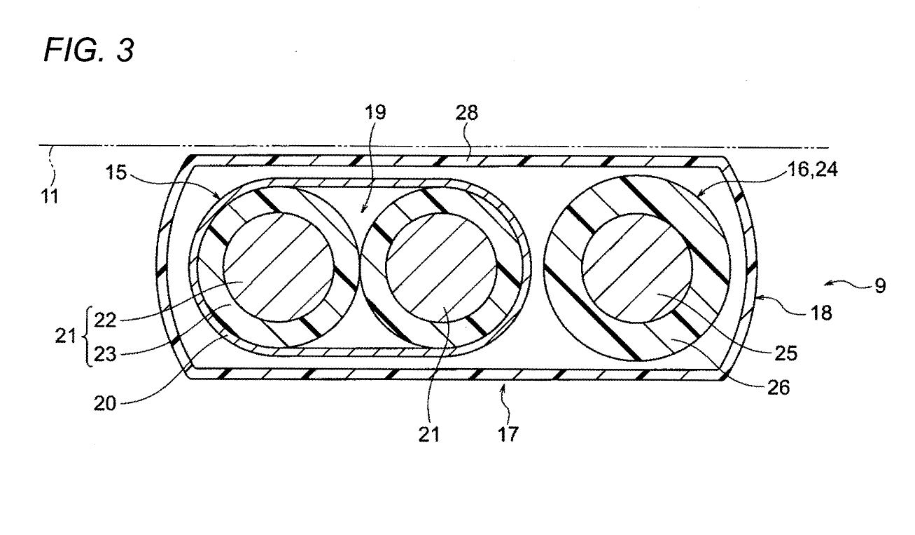

Embodiment 1 will be described below with reference to the drawings. FIG. 1 is a schematic view showing a state in which a wire harness according to Embodiment 1 of the invention has been arranged. FIG. 2 is a perspective view of the wire harness according to Embodiment 1. FIG. 3 is a sectional view taken on line A-A in FIG. 2.

In the embodiment, the invention is applied to a wire harness to be arranged in a hybrid car (which may be replaced by an electric car or a general).

In FIG. 1, a hybrid car 1 is a vehicle driven by a mixture of two power sources, that is, an engine 2 and a motor unit 3. Electric power is supplied from a battery 5 (battery pack) to the motor unit 3 through an inverter unit 4. In the embodiment, the engine 2, the motor unit 3, and the inverter unit 4 are mounted in an engine room 6 where there are front wheels etc. On the other hand, the battery 5 is mounted in a car rear portion 7 where there are rear wheels etc. However, the battery 5 may be mounted in a car cabin located at the rear of the engine room 6.

The motor unit 3 and the inverter unit 4 are connected through a high-voltage wire harness 8. On the other hand, the battery 5 and the inverter unit 4 are also connected through a wire harness 9. An intermediate portion 10 of the wire harness 9 is arranged in a vehicle underfloor 11. In addition, the intermediate portion 10 is arranged substantially in parallel to the vehicle underfloor 11. The vehicle underfloor 11 is a well-known body, which is also a so-called panel member. Through holes are formed in predetermined positions of the vehicle underfloor 11. The wire harness 9 is watertightly inserted into the through holes.

The wire harness 9 and the battery 5 are connected through a junction block 12 that is provided in the battery 5. A rear end 13 of the wire harness 9 is electrically connected to the junction block 12 by a well-known method. On the other hand, a front end 14 of the wire harness 9 is electrically connected to the inverter unit 4 by a well-known method.

The motor unit 3 has a configuration including a motor and a generator. On the other hand, the inverter unit 4 has a configuration including an inverter and a converter. The motor unit 3 is formed as a motor assembly including a shield case. The inverter unit 4 is also formed as an inverter assembly including a shield case. The battery 5 is a modularized one based on Ni-MH or Li-ion. For example, an electric storage device such as a capacitor may be used. The battery 5 is not limited especially as long as it can be used in the hybrid car 1 or an electric car. In FIG. 2, the wire harness 9 is provided with a shielded high-voltage circuit 15. The shielded high-voltage circuit 15 is a high-voltage circuit covered with a shielding member, as will be described below.

In addition to the shielded high-voltage circuit 15, the wire harness 9 is provided with a low-voltage circuit 16, a resin tube 17, connectors (not shown) provided at terminals of the shielded high-voltage circuit 15 and the low-voltage circuit 16 respectively, a plurality of clamps (not shown) and grommets attached to the external surface of the resin tube 17, etc.

Of such a configuration, the shielded high-voltage circuit 15, the low-voltage circuit 16, and the resin tube 17 are formed as a harness body 18.

In FIG. 2 and FIG. 3, the shielded high-voltage circuit 15 has a configuration including a high-voltage circuit 19 and a shielding member 20. In the shielded high-voltage circuit 15, the high-voltage circuit 19 is covered with the shielding member 20 all over the length. The shielded high-voltage circuit 15 is formed with length required for electric connection. In the embodiment, the wire harness 9 is formed to be long enough to electrically connect the inverter unit 4 and the battery 5 (junction block 12, see FIG. 1) with each other.

The high-voltage circuit 19 is formed out of two high-voltage unshielded electric wires 21. Incidentally, the number of unshielded electric wires 21 is one of examples. It is not limited to two, but may be three or more. Each high-voltage unshielded electric wire 21 has a configuration including a conductor 22, and an insulator 23 the conductor 22 is covered with. Each high-voltage unshielded electric wire 21 is an electric wire having a shieldless structure and a sheathless structure. The two unshielded electric wires 21 are disposed in parallel.

Incidentally, the high-voltage unshielded electric wires 21 may be also referred to as non-shielded electric wires.

The conductor 22 is produced out of copper, a copper alloy, aluminum or an aluminum alloy. In the embodiment, an aluminum conductor is used due to a merit that it is low in price and light in weight. The conductor structure of the conductor 22 may be either a sectionally circular conductor structure in which strands have been twisted, or a rod-like conductor structure that has a rectangular shape or a circular shape in section (for example, a conductor structure that serves as a rectangular single core or a circular single core. In this case, the electric wire itself also has a rod-like shape). The insulator 23 is formed on the outer surface of the aforementioned conductor 22 by extrusion molding.

The insulator 23 is formed on the outer circumferential surface of the conductor 22 by extrusion molding using a thermoplastic resin material. In the embodiment, the insulator 23 is formed as coating having a circular shape in section. The insulator 23 is formed with a predetermined thickness. Various kinds of well-known resins may be used as the thermoplastic resin. For example, one may be selected suitably from polymers such as polyvinylchloride resin, polyethylene resin, polypropylene resin, etc.

Incidentally, although the high-voltage unshielded electric wires 21 configured thus are used as the high-voltage circuit 19 in the embodiment, the high-voltage circuit 19 is not limited thereto. That is, the high-voltage circuit 19 may have a configuration in which an insulator is provided on a well-known bus bar.

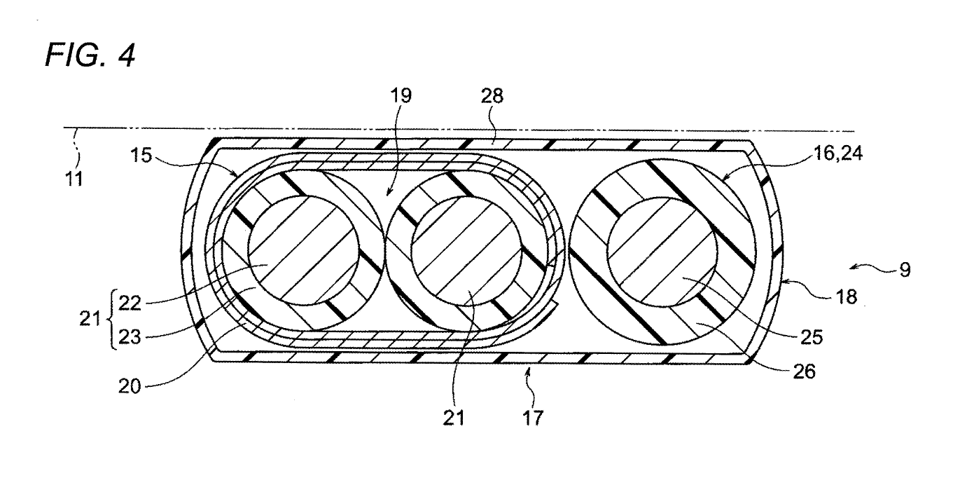

The shielding member 20 is an electromagnetically shielding member (electromagnetic wave shielding member) with which the two high-voltage unshielded electric wires 21 are covered together. In the embodiment, a braid is used as the shielding member 20. Incidentally, another example will be described later with reference to FIG. 4. The braid is formed out of extremely thin metal strands having conductivity and woven into a cylindrical shape or a sheet-like shape. When the braid is cylindrical, the two high-voltage unshielded electric wires 21 are stored in parallel inside the braid. On the other hand, when the braid has a sheet-like shape, the braid is wound around the two high-voltage unshielded electric wires 21 by one or more turns. Incidentally, it will go well only if the shielding member 20 can obtain an electromagnetically shielding function. It is preferable that the shielding member 20 is formed to be extremely thin.

The shielding member 20 is formed to be substantially as long as the whole length of each of the two high-voltage unshielded electric wires 21 (high-voltage circuit 19). A terminal portion of the shielding member 20 is connected to a shield case or the like (not shown) of the inverter unit 4 (see FIG. 1) through the aforementioned not-shown connector (for example, shield connector).

When the two high-voltage unshielded electric wires 21 (high-voltage circuit 19) are covered with the shielding member 20, the shielded high-voltage circuit 15 is completely formed. The low-voltage circuit 16 is formed out of a single low-voltage unshielded electric wire 24. Incidentally, the number of low-voltage unshielded electric wires 24 is one of examples. The number of low-voltage unshielded electric wires 24 is not limited to one, but may be plural. The low-voltage unshielded electric wire 24 has a configuration including a conductor 25, and an insulator 26 the conductor 25 is covered with. The low-voltage unshielded electric wire 24 is an electric wire having a sheathless structure in the same manner as the high-voltage unshielded electric wires 21.

The low-voltage unshielded electric wire 24 is disposed adjacently to the high-voltage circuit 19. That is, the low-voltage unshielded electric wire 24 is disposed adjacently to the two high-voltage unshielded electric wires 21 arranged in parallel. To say other words, the low-voltage circuit 16 is disposed in parallel with the shielded high-voltage circuit 15.

The resin tube 17 is a component formed out of resin and into a tubular shape. The resin tube 17 is formed so that it can store the shielded high-voltage circuit 15 and the low-voltage circuit 16 that have been arranged in parallel. In addition, the resin tube 17 is formed to be so long that the shielded high-voltage circuit 15 and the low-voltage circuit 16 can be inserted into the resin tube 17 and stored thereby, and so thick that those circuits can be protected. The resin tube 17 is formed to be long enough to pass through the vehicle underfloor 11 and extend from the front of the vehicle to the back of the same. The resin tube 17 is a suitable member for protecting electric wires each having a sheathless structure.

The resin tube 17 is formed into a shape in which there is no seam or no slit communicating from the outer surface of the resin tube 17 to the inner surface of the same. That is, the resin tube 17 is formed into a shape in which the shielded high-voltage circuit 15 and the low-voltage circuit 16 can be kept away from outside moisture (the shielded high-voltage circuit 15 and the low-voltage circuit 16 can be waterproofed). The resin tube 17 is, for example, formed into an illustrated shape, including flexible tube portions 27 having flexibility, and straight tube portions 28 serving as parts to be arranged straightly. To say other words, the resin tube 17 is, for example, formed into an illustrated shape, including flexible tube portions 27 that can be bent, and straight tube portions 28 that are higher in rigidity than the flexible tube portions 27.

The resin tube 17 has a plurality of flexible tube portions 27 and a plurality of straight tube portions 28, and is formed so that the flexible tube portions 27 and the straight tube portions 28 can be disposed alternately. That is, the resin tube 17 is formed so that the flexible tube portions 27 and the straight tube portions 28 can be connected continuously in the extending direction of the shielded high-voltage circuit 15 and the low-voltage circuit 16.

The flexible tube portions 27 are formed and disposed in accordance with the shape of attachment to a vehicle (the shape of a destination where the wire harness should be wired, or the shape of a target to which the wire harness should be fixed). Specifically, the flexible tube portions 27 are formed and disposed in accordance with sections where the wire harness must be bent. In addition, the flexible tube portions 27 are formed to be long enough to be bent. In addition, each flexible tube portion 27 is formed into a substantially rectangular shape in section (flat shape). However, the flexible tube portion 27 may be formed into a circular shape in section if it is not a part corresponding to the vehicle underfloor 11.

The flexible tube portions 27 are formed so that they can be bent at desired angles respectively during packing or transportation and during wiring path arrangement on the vehicle after the wire harness 9 is manufactured. The flexible tube portions 27 are formed so that they can be bent into desired bent shapes and they can be restored to their original unbent shapes naturally.

In the embodiment, each flexible tube portion 27 is formed into a bellows tube shape. However, the shape of the flexible tube portion 27 is not limited especially but it will go well if it has flexibility. Specifically, the flexible tube portion 27 is formed to have recess portions 29 and protruding portions 30 extending circumferentially so as to make the recess portions 29 and the protruding portions 30 continuous and alternate in the tube axis direction (the extending direction of the shielded high-voltage circuit 15 and the low-voltage circuit 16). As is understood from the aforementioned description, the parts where the flexible tube portions 27 are disposed are formed into shapes serving just like corrugated tubes. To say other words, the resin tube 17 is formed into a shape in which corrugated tubes are provided partially. Since the resin tube 17 includes the parts serving as corrugated tubes as described above, the resin tube 17 may be referred to as a “corrugated tube”, a “partially corrugated tube” or the like.

On the other hand, each straight tube portion 28 is formed as a part that cannot be bent during packing or transportation or during wiring path arrangement of the wire harness 9. Here, the part that cannot be bent means a part that is not aggressively provided with flexibility. In addition, the straight tube portion 28 is formed into a substantially rectangular shape in section (or formed into a flat shape).

To say other words, the straight tube portion 28 is formed into a straight tube shape that is substantially rectangular in section.

The straight tube portions 28 are formed to be disposed at least in the vehicle underfloor 11. In addition, the straight tube portions 28 are formed in positions or lengths corresponding to the shape of attachment to the vehicle.

Each straight tube portion 28 is formed into a straight tube shape (linear tube) as described above. In addition, it can be said that the straight tube portion 28 has rigidity. Therefore, the straight tube portion 28 may be also referred to as a “linear tube portion”, a “rigid portion” or the like. In the aforementioned configuration and structure, the wire harness 9 is manufactured as follows. That is, in the process for manufacturing the wire harness 9, the shielded high voltage circuit 15 and the low-voltage circuit 16 are inserted into the resin tube 17 from its one end to the other end. At this time, since the resin tube 17 is formed into a substantially straight shape as a whole by molding out of resin, the shielded high voltage circuit 15 and the low-voltage circuit 16 can be inserted straightly. That is, the shielded high voltage circuit 15 and the low-voltage circuit 16 can be inserted smoothly. In addition, in the process for manufacturing the wire harness 9, clamps, grommets, boots, etc. are attached to predetermined positions in the outer surface of the resin tube 17. Further, connectors are provided in the terminal parts of the shielded high-voltage circuit 15 and the terminal parts of the low-voltage circuit 16 respectively. Thus, the wire harness 9 is manufactured. The wire harness 9 manufactured thus is put into a state in which flexible portions 27 located in predetermined positions have been folded and bent. Thus, the wire harness 9 is completely packed. The packed wire harness 9 can be made compact. In the compact state, the wire harness 9 is transported to a site in which the wire harness 9 should be installed on a vehicle. In the site in which the wire harness 9 should be installed on a vehicle, of the wire harness 9, a long part corresponding to the vehicle underfloor 11 is first attached to the vehicle. In the wire harness 9, a straight tube portion 28 of the resin tube 17 is disposed as the long part corresponding to the vehicle underfloor 11. Therefore, the wire harness 9 can be attached in the state where bending is suppressed. At this time, the wire harness 9 can be attached with good workability.

After the long part corresponding to the vehicle underfloor 11 is fixed by clamps or the like, the other parts are attached while parts of the flexible tube portions 27 are bent (flexed) in the resin tube 17. When a series of operations for attachment are completed, the wire harness 9 is brought into a state where it has been arranged in a desired path.

The wire harness 9 according to the invention has been described above with reference to FIG. 1 to FIG. 3. According to the wire harness 9, the part of the harness body 18 is formed so that the shielded high-voltage circuit 15 and the low-voltage circuit 16 can be stored in a single resin tube 17 at the same time and in parallel. Thus, there is an effect that the number of components can be reduced in comparison with that in the background-art example.

In addition, according to the wire harness 9, the high-voltage unshielded electric wires 21 are used as the high-voltage circuit 19 so that they can be made into thinner electric wires than well-known shielded electric wires. As a result, there is an effect that space saving can be attained.

In addition, according to the wire harness 9, each of the high-voltage circuit 19 and the low-voltage circuit 16 has a sheathless structure. Accordingly, there is an effect that the wire harness 9 can be thinned at least correspondingly to the absence of any sheath. That is, there is an effect that space saving can be attained.

In addition, according to the wire harness 9, the shielding member 20 is formed out of a braid. Accordingly, the wire harness 9 can be prevented from being thickened even when the high-voltage circuit 19 is covered with the shielding member 20 formed thus. As a result, there is an effect that space saving can be attained.

In addition, according to the wire harness 9, due to the aforementioned space saving, there is an effect that the wire harness 9 can be arranged with reduced height in the vehicle underfloor 11 even when the vehicle underfloor 11 is short in distance from the ground.

In addition, according to the wire harness 9, the resin tube 17 having a substantially rectangular shape in section (flat shape) is used. For example, in comparison with a substantially circular shape in section, there is an effect that the distance from the ground can be secured even when the wire harness 9 is arranged in the vehicle underfloor 11. That is, there is an effect that the wire harness 9 can be arranged with reduced height.

In addition, according to the wire harness 9, the resin tube 17 including the flexible tube portions 27 and the straight tube portions 28 is used. Accordingly, there is an effect that the flexible tube portions 27 and the straight tube portions 28 can be used suitably in accordance with parts to be bent and parts to be made straight.

### Embodiment 2

Embodiment 2 will be described below with reference to the drawings. FIG. 4 is a sectional view of a wire harness according to a modification. Incidentally, constituent members fundamentally the same as those in the aforementioned Embodiment 1 are referenced correspondingly, and detailed description thereof will be omitted.

In FIG. 4, a harness body 18 of a wire harness 9 has a configuration including a shielded high-voltage circuit 15, a low-voltage circuit 16, and a resin tube 17. The shielded high-voltage circuit 15 has a configuration in which a high-voltage circuit 19 is covered with a shielding member 20 all over the length. The shielded high-voltage circuit 15 is formed with length required for electric connection. The high-voltage circuit 19 has a configuration including two high-voltage unshielded electric wires 21. Incidentally, the number of high-voltage unshielded electric wires 21 is one of examples. Each high-voltage unshielded electric wire 21 is an electric wire having a shieldless structure and a sheathless structure including a conductor 22 and an insulator 23. The two high-voltage unshielded electric wires 21 are disposed in parallel.

The shielding member 20 is an electromagnetically shielding member with which the two high-voltage unshielded electric wires 21 are covered together. In the embodiment, a tape made of metal foil (or a sheet made of metal foil) is used as the shielding member 20. The shielding member 20 is use to be thin and to be wound around the two high-voltage unshielded electric wires 21 by one or more turns. When the two high-voltage unshielded electric wires 21 (high-voltage circuit 19) are covered with the shielding member 20 configured thus, the shielded high-voltage circuit 15 is completely formed. In the aforementioned configuration and structure, the wire harness 9 is manufactured as follows. That is, the shielded high voltage circuit 15 and the low-voltage circuit 16 are inserted into the resin tube 17, which has been formed out of resin and into a substantially straight shape as a whole, from its one end to the other end. In addition, in the process for manufacturing the wire harness 9, clamps, grommets, boots, etc. are attached to predetermined positions in the outer surface of the resin tube 17. Further, connectors are provided in the terminal parts of the shielded high-voltage circuit 15 and the terminal parts of the low-voltage circuit 16 respectively. Thus, the wire harness 9 is manufactured.

The wire harness 9 according to Embodiment 2 has been described above with reference to FIG. 4. According to the wire harness 9, the part of the harness body 18 is formed so that the shielded high-voltage circuit 15 and the low-voltage circuit 16 can be stored in a single resin tube 17 at the same time and in parallel. Thus, there is an effect that the number of components can be reduced in comparison with that in the background-art example. That is, the same effect as that in Embodiment 1 can be obtained.

In addition, according to the wire harness 9 according to Embodiment 2, the high-voltage unshielded electric wires 21 are used as the high-voltage circuit 19 so that they can be made into thinner electric wires than well-known shielded electric wires. As a result, there is an effect that space saving can be attained. That is, the same effect as that in Embodiment 1 can be obtained.

In addition, it is a matter of course that various changes can be made on the invention without changing the gist of the invention.

In the aforementioned description, a resin tube 17 including flexible tube portions 27 and straight tube portions 28 is used. However, the invention is not limited thereto. That is, a resin tube that is entirely formed by a flexible tube portion 27 may be used. In this case, it is a matter of course that there is an effect that the wire harness can be bent at any desired position.

Feathers of the aforementioned embodiments of the wire harnesses according to the invention will be summarized and listed briefly in the following paragraphs [1] to [7] respectively.

[1] A wire harness including a high-voltage circuit including a plurality of unshielded electric wires, and a low-voltage circuit, wherein the high-voltage circuit and the low-voltage circuit are disposed in parallel, and wherein the high-voltage circuit is stored in a resin tube together with the low-voltage circuit in a state in which the high-voltage circuit is covered with a shielding member.

[2] The wire harness according to the aforementioned paragraph [1], wherein:

each of the unshielded electric wires is an electric wire having a sheathless structure including a conductor and an insulator.

[3] The wire harness according to the aforementioned paragraph [1] or [2], wherein:

the shielding member is one of a braid, a tape made of metal foil, and a sheet made of metal foil.

[4] The wire harness according to any one of the aforementioned paragraphs [1] to [3], wherein the low-voltage circuit includes one or a plurality of unshielded electric wires which have a sheathless structure including a conductor and an insulator.

[5] The wire harness according to any one of the aforementioned paragraphs [1] to [4], wherein the wire harness is arranged in a site including a vehicle underfloor.

[6] The wire harness according to the aforementioned paragraph [5], wherein at least a part of the resin tube corresponding to the vehicle underfloor has a flat shape in which the high-voltage circuit and the low-voltage circuit is stored so as to be arrayed in parallel, and the resin tube includes a flexible tube portion having flexibility, and a straight tube portion serving as a part to be arranged straightly.

[6] The wire harness according to the aforementioned paragraph [5], wherein at least a part of the resin tube corresponding to the vehicle underfloor has a flat shape in which the high-voltage circuit and the low-voltage circuit is stored so as to be arrayed in parallel, and the resin tube includes only a flexible tube portion having flexibility.

Although the invention has been described in detail and with reference to its specific embodiments, it is obvious for those skilled in the art that various changes or modifications can be made on the invention without departing from the spirit and scope of the invention.

According to the invention, there is an effect that space saving and reduction in number of components can be attained. The invention attaining the effect is useful for a wire harness in which a high-voltage circuit and a low-voltage circuit are disposed in parallel.

What is claimed is:

1. A wire harness comprising:
a high-voltage circuit comprising a plurality of unshielded electric wires; and
a low-voltage circuit,
wherein the high-voltage circuit and the low-voltage circuit are disposed in parallel,
wherein the high-voltage circuit is stored in a resin tube together with the low-voltage circuit in a state in which the high-voltage circuit is covered with a shielding member,
wherein each of the unshielded electric wires is an electric wire having a sheathless structure comprising a conductor and an insulator, and
wherein the shielding member is one of a braid, a tape made of metal foil, and a sheet made of metal foil.

2. The wire harness according to claim 1,
wherein the low-voltage circuit comprises one or a plurality of unshielded electric wires which have a sheathless structure comprising a conductor and an insulator.

3. The wire harness according to claim 1,
wherein the wire harness is arranged in a site comprising a vehicle underfloor.

4. The wire harness according to claim 3,
wherein at least a part of the resin tube corresponding to the vehicle underfloor has a flat shape in which the high-voltage circuit and the low-voltage circuit is stored so as to be arrayed in parallel, and the resin tube comprises a flexible tube portion having flexibility and a straight tube portion serving as a part to be arranged straightly.

5. The wire harness according to claim 3, wherein at least a part of the resin tube corresponding to the vehicle underfloor has a flat shape in which the high-voltage circuit and the low-voltage circuit is stored so as to be arrayed in parallel, and the resin tube comprises only a flexible tube portion having flexibility.
